(19) United States
(12) Patent Application Publication
(10) Pub. No.: US 2008/0273294 A1
(43) Pub. Date: Nov. 6, 2008

(54) Protective case for a multi-media device

(76) Inventor: Min-Li Tseng, Ren-De Hsiang (TW)

Correspondence Address: Li-Min TSENG, P.O. Box 6-9 717, Tainan, TW

(21) Appl. No.: 11/893,773

(22) Filed: Aug. 20, 2007

(30) Foreign Application Priority Data
May 5, 2007 (TW) 96207265

(51) Int. Cl. H05K 5/03

(52) U.S. Cl. 361/679

(57) ABSTRACT

A protective case for a multi-media device includes a transparent body and a supporting strip. The transparent body is composed of a main base, a decorative strip with colored streaks and a cover coated with a layer of pearl silver color. The supporting strip is threadably combined with the underside of the main base, made of an elastic steel plate wrapped around by a layer of soft rubber. The decorative strip and the cover are covered on the transparent body, with a multi-media device placed in the transparent body. Thus the decorative strip and the cover beautify the multi-media device with brilliance of the colored streaks and the pearl silver color.

### BACKGROUND OF THE INVENTION

1. Field of the Invention

This invention relates to a protective case for a multi-media device, particularly to one embellishing the multi-media device and possible to function as a display base for placing it on a table, changing the outer look of the multi-media device with brilliance and furnishing it with more practicality.

2. Description of the Prior Art

Nowadays, a video audio player such as iPod, the hottest item in the market, has been improved to have a larger capacity and more functions, and users can listen to music via MP3 players and enjoy movies by means of a LED screen provided on iPod. The iPod can be held in a hand for viewing a movie as shown in FIG. 1, or can be placed on a table for enjoying movies or listening music. However, it is not so convenient to hold it in a hand, and not so suitable to be placed on a table.

### SUMMARY OF THE INVENTION

The features of the invention are a decorative strip placed on a main base of a body of a protective case, and a cover with a layer of pearl silver color closed on the decorative strip and combined with the main base. The decorative strip is made of colored material and provided with plural projecting streaks on its surface. So the brilliant pearl silver color and the colored streaks can generate brilliance to the protective case with a multi-media device held therein.

### BRIEF DESCRIPTION OF DRAWINGS

This invention will be better understood by referring to the accompanying drawings, wherein:

FIG. 1 is a perspective view of a conventional multi-media device in a using condition;

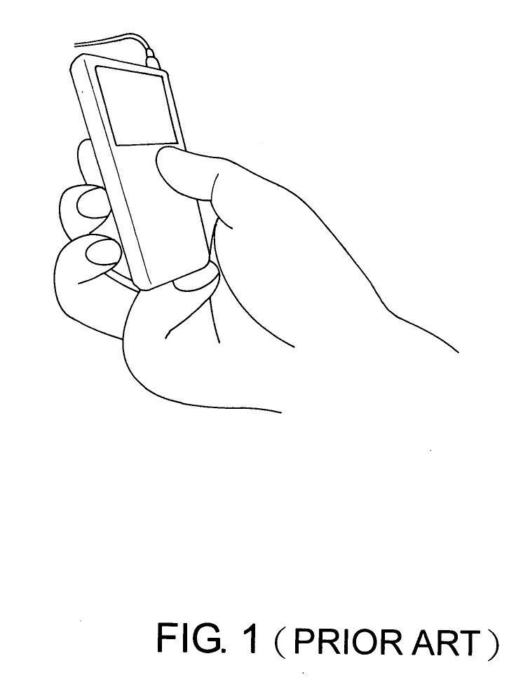

FIG. 2 is an exploded perspective view of a protective case for a multi-media device in the present invention;

FIG. 3 is a perspective view of the protective case for a multi-media device in the present invention;

FIG. 4 is a cross-sectional view of a cover and a main base combined together in the present invention;

FIG. 5 is a partial perspective view of an elastic steel strip in the present invention;

FIG. 6 is a perspective view of an earphone line held in the protective case in the present invention; and,

FIG. 7 is a side view of the elastic strip being warped upward from the warped-down condition in the present invention.

### DETAILED DESCRIPTION OF THE PREFERRED EMBODIMENT

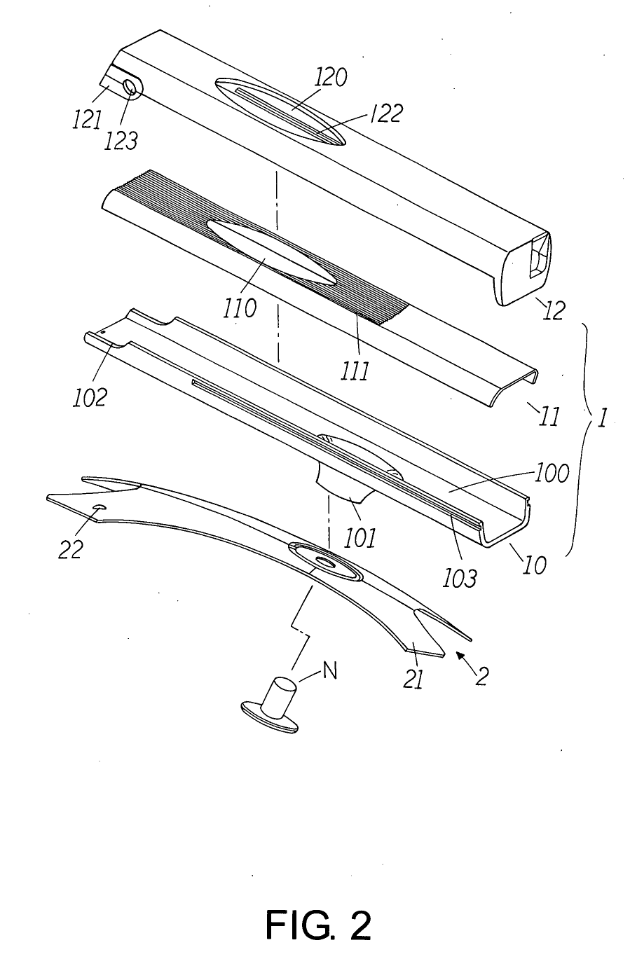

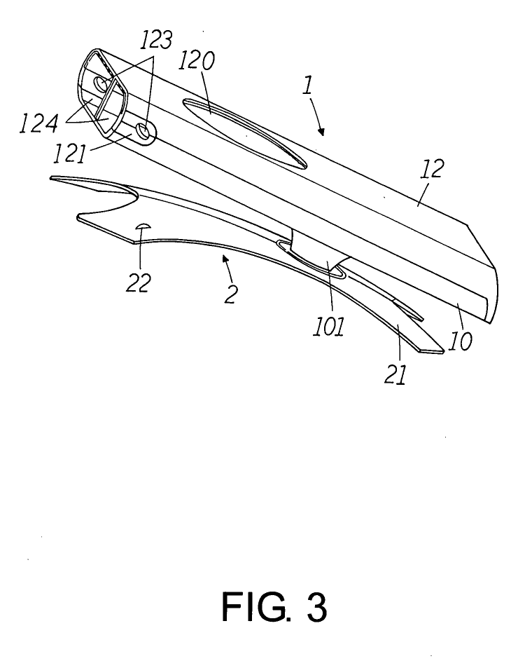

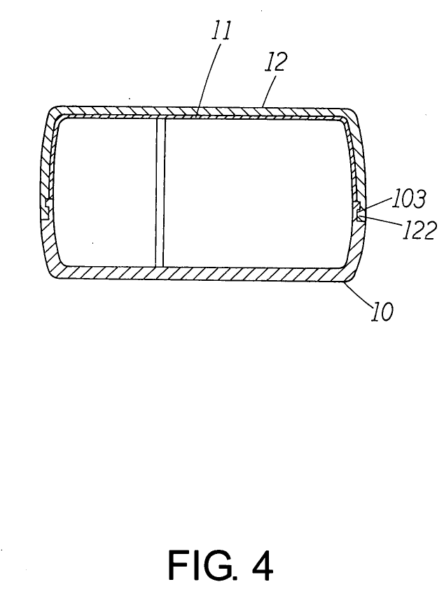

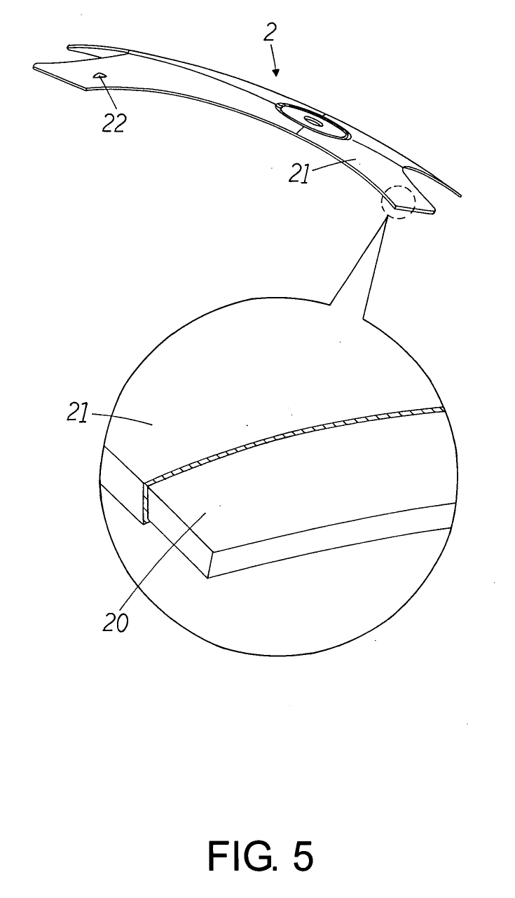

A preferred embodiment of a protective case for a multi-media device in the present invention, as shown in FIGS. 2-7, includes a transparent body 1 and an elastic supporting strip 2 as main components.

The transparent body 1 is composed of a main base 10, a decorative strip 11, and an elongate cover 12.

The elongate main base 10 has a lengthwise recess 100 and a threaded post 101 extending down from an underside, a fitting surface 102 and a fitting ridge 103 formed on two bent lengthwise walls.

The elongate decorative strip 11 is placed on the main base 10, made of colored material, provided with a center oval hole 110 and plural protruding slender streaks 111 spaced apart closely on an upper surface.

The elongate cover 12 is made of transparent plastic, covering on the decorative strip 11 and fitted with the elongate main base 10, coated with a layer of pearl silver color and provided with a central oval hole 120, a fitting surface 121 formed on an outer surface of a lower end, a fitting groove 122 formed in an inner surface, a hanging hole 123 bored in two sides of the lower end and a plug hole 124 bored in an upper end surface for a plug for charging and connect to a walkman.

The elastic supporting strip 2 is fixed with the threaded post 101 of the main base 10 with a screw (N), made of a steel plate 20 and a layer of soft rubber 21 wrapped around the steel plate 20, shaped curved and possible to warp up or down and provided with a slip-stop projection 22 on a lower end surface

In assembling, firstly, a multi-media device (A) is placed in the recess 100 of the main base 10, then the decorative strip 11 covered on the multi-media device (A), and finally the cover 12 is covered on the main base 10, with the fitting surface 121 fitting with the fitting surface 102 of the main base 10, and with the fitting ridge 103 of the main base 10 fitting with the fitting groove 122 of the cover 12.

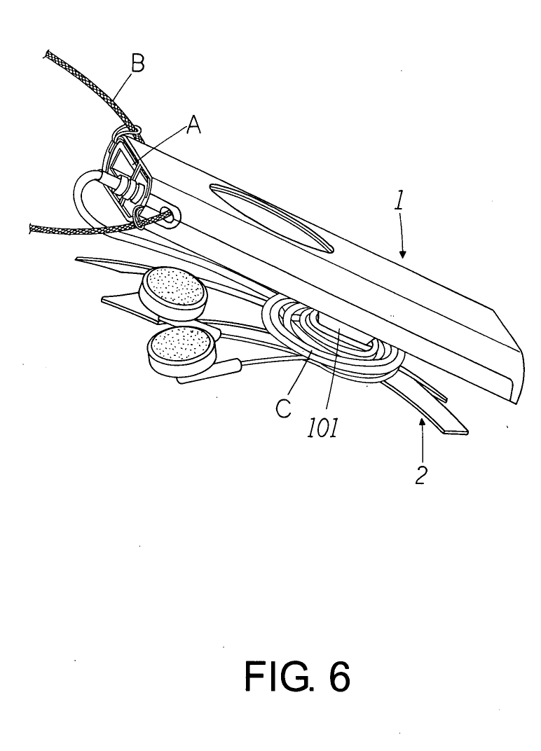

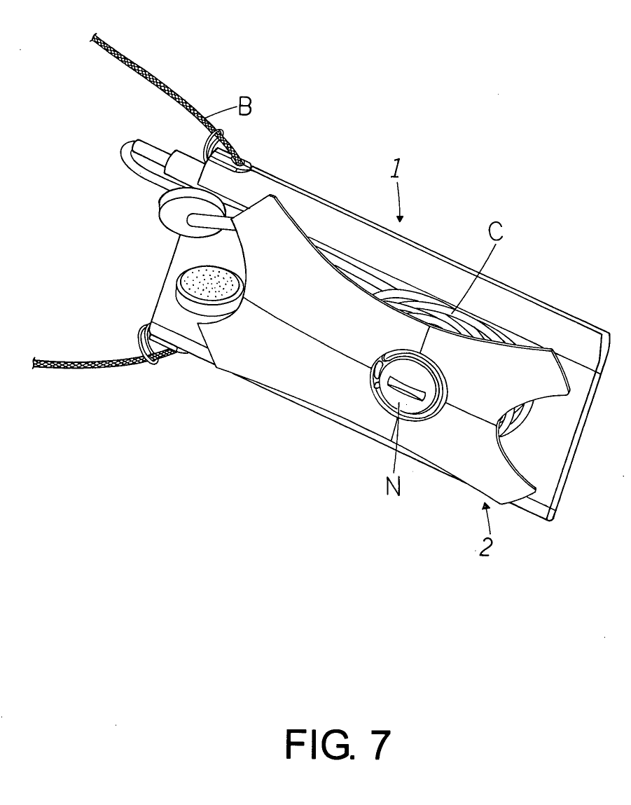

Further, a hang string (B) is inserted through the hanging hole 123 of the cover 12 for a user to hang a multi-media device (A) put in the protective case on the neck, and it can be carried around conveniently. Next, in using, if the protective case together with a multi-media device (A) is to be hung on a neck of a user, the hanging string (B) is hung on the neck, and then the decorative strip 11 with the colored protruding slender streaks 111 together with the pearl silver color generate brilliant reflection to give the multi-media device an attractive nice appearance. Besides, to put away an earphone line (C), it can be kept stably in a space between the elastic supporting strip 2 and a multi-media device (A), with the steel plate 20 made to warp up as shown in FIGS. 6 and 7.

The invention has the following advantages as can be understood from the foresaid description.

1. It can be pinched on a belt by means of the supporting strip 2, very convenient to be carried around.

2. The supporting strip can be used as a display means for a multi-media device, when it is made to warp down, making the supporting strip 2 form an elevated angle so that the protective case with the multi-media device may be placed on a table for using the multi-media device for enjoying videos.

3. An earphone line can be stored between a multi-media device and the supporting strip 2 for convenience of use.

4. The hanging string can be inserted through the hanging hole 123 so a multi-media device placed in the protective case can be carried around, by hanging it on a neck of a user, suspending in front of the breast, showing off its brilliant, shining and milt-colored appearance.

While the preferred embodiment of the invention has been described above, it will be recognized and understood that various modifications may be made therein and the appended claims are intended to cover all such modifications that may fall within the spirit and scope of the invention.

What is claimed is:

1. A protective case for a multi-media device, said case comprising:
a body composed of a main base, a decorative strip, a cover, said main body provided with a lengthwise recess;
said decorative strip closed on said main base, made of a transparent material, provided with plural projecting streaks spaced apart closely in parallel on an outer surface and an oval hole in an intermediate portion; and,
said cover closing on said decorative strip and fitting tightly with said main base, made of transparent material, having a hole respectively at two sides.

2. A protective case for a multi-media device, said case comprising:
a body made of transparent material, having a hollow space for placing a multi-media device and a threaded post extending down from an intermediate portion of an underside;
a supporting strip threadably combined with said threaded post of said body, made of an elastic steel plate and wrapped around by a layer of soft rubber, possible to be held on a belt with a screw and also to be placed on a table.

3. The protective case for a multi-media device as claimed in claim 1, wherein said decorative strip is made of brilliantly colored material.

4. The protective case for a multi-media device as claimed in claim 2, wherein said supporting strip is provided with a slip-stop projection on an upper surface for tightly secured on a belt.

5. The protective case for a multi-media device as claimed in claim 1, wherein said main base is provided with a fitting ridge, and said cover is provided with a fitting groove to fit with said fitting ridge of said main base so as to combine said main base with said cover together.
